(19) United States
(12) Patent Application Publication
(10) Pub. No.: US 2022/0037369 A1
(43) Pub. Date: Feb. 3, 2022

(54) SONOS Memory and Method for Making the Same

(71) Applicant: Shanghai Huali Microelectronics Corporation, Shanghai (CN)

(72) Inventors: Xiaoliang Tang, Shanghai (CN); Naoki Tsuji, Shanghai (CN); Haoyu Chen, Shanghai (CN); Hua Shao, Shanghai (CN)

(73) Assignee: Shanghai Huali Microelectronics Corporation, Shanghai (CN)

(21) Appl. No.: 17/352,518

(22) Filed: Jun. 21, 2021

(30) Foreign Application Priority Data
Jul. 31, 2020 (CN) 202010757304.8

(51) Int. Cl. H01L 27/12; H01L 21/762

(52) U.S. Cl. CPC H01L 27/1207; H01L 27/1157; H01L 21/76243

(57) ABSTRACT

The invention provides a method for manufacturing a SONOS memory, including: providing a substrate, wherein a selective transistor gate and a storage transistor gate are formed on the substrate of a storage area; forming a silicon epitaxial layer on the upper surface of the substrate of the storage area on both sides of the selective transistor gate and on both sides of the storage transistor gate, wherein the silicon epitaxial layer is used to separately form a source and a drain of a selective transistor and a storage transistor; and forming a metal salicide layer on an upper portion of the silicon epitaxial layer. The present application further provides the SONOS memory. The present application can improve the yield of the formed SONOS memory and effectively improve the device performance of the formed SONOS memory, and the device performance of the formed SONOS memory can be effectively improved.

### CROSS-REFERENCES TO RELATED APPLICATIONS

This application claims the priority to Chinese patent application No. 202010757304.8 filed on Jul. 31, 2021, and entitled “SONOS MEMORY AND METHOD FOR MAKING THE SAME”, the disclosure of which is incorporated herein by reference in its entirety.

### TECHNICAL FIELD

The present application relates to the field of semiconductor devices and manufacturing thereof, in particular to a SONOS memory structure and a manufacturing method thereof.

### BACKGROUND

Since the early day when Dr. Jack Kilby of Texas Instruments invented the integrated circuit, scientists and engineers have made numerous inventions and improvements in the aspects of semiconductor device and process. The size of semiconductors has been significantly reduced in the past 50 years, leading to a continuous increase in the processing speed and a continuous reduction in the power consumption. So far, the development of semiconductors generally follows the Moore's Law. The Moore's Law generally indicates that the number of transistors in a dense integrated circuit doubles approximately every two years. Currently, the semiconductor process is developing towards a node below 20 nm, and some companies are working on the 14-nm process. A reference is provided herein, wherein the diameter of a silicon atom is about 0.2 nm, which means that the distance between two independent components manufactured by means of the 20-nm process is only about the sum of the diameters of a hundred silicon atoms.

Currently, in an integrated circuit, according to a conventional bulk silicon process, a memory cell includes two independent transistor structures, i.e., a storage transistor and a selective transistor matching the storage transistor. The storage transistor has a Silicon (gate)-Oxide-Nitride-Oxide-Silicon (substrate) (SONOS) structure and is used for storing electric charges, so as to implement data storage by means of different Vt states. The selective transistor is a conventional MOS transistor used for turning on and off the storage transistor.

As described above, the manufacturing of semiconductor devices becomes increasingly challenging and develops towards the feasible physical limit. As the size of very large scale integrated circuits decreases continuously, the limitations on the manufacturing process and material properties becomes increasingly significant, rendering the reduction of the size of planar transistors increasingly difficult. Corresponding to the planar transistor manufactured by the conventional bulk silicon process, the fully depleted silicon-on-insulator (FDSOI) device is considered to be a novel planar device with great potential due to the features of low power consumption and simplified production process. The fully depleted silicon-on-insulator has an ultra-thin insulating layer, i.e., a buried oxide layer. The buried oxide layer can effectively limit electrons flowing from the source to the drain, thereby greatly reducing the leakage current flowing from the channel to the substrate. Moreover, by applying a body bias, the FDSOI transistor can operate extremely quickly under low voltage, thereby greatly improving the energy efficiency.

At present, in a SONOS memory related to the SOI process, only a logic area of the

SONOS memory relates to the SOI process and thus is used as a low power consumption device area. The memory cell portion of the SONOS memory has a structure the same as the conventional bulk silicon process structure. A SOI layer on a SOI silicon wafer needs to be etched and removed to form a substrate area the same as that of the bulk silicon process, and then the related SOI process is performed, so that a high-voltage operation of the SONOS memory is not affected by the SOI layer.

Since the conventional bulk silicon process is still used in the SONOS memory cell area, during silicon epitaxial growth of the upper surface of the SOI layer in the logic device area, the upper surface of the substrate in the SONOS area does not undergo silicon epitaxial growth.

Reference is made to FIG. 1 to understand the above description. Referring to FIG. 1, a memory cell area and a logic area of a SONOS memory which are separated from each other by an isolation dielectric are formed in a substrate 201, wherein the memory cell area is the same as the existing bulk silicon process structure. A SONOS memory cell in the memory cell area includes: an N-type deep well 101, a selective transistor P-type well 102, a storage transistor P-type well 103, a selective transistor gate 105 isolated from the selective transistor well 102 via an oxide layer 104, and a storage transistor gate 107 isolated from the storage transistor well 103 via an ONO layer 106, which are formed in the substrate 201. The outer sides of the selective transistor gate 105 and the storage transistor gate 107 are each provide with a first sidewall 110 and a second sidewall 120. More specifically, the first sidewall includes an ONO structure. Generally, the thickness of the first sidewall 110 determines the distance from the ion implantation position in a source-drain extension region to the gate, and the thickness of the second sidewall 120 defines the distance from the gate to the source and drain.

The SOI process is adopted in the logic area, including a composite substrate composed of a silicon base layer (the upper portion of which is a logic well 210), a buried oxide layer 220, and a silicon surface layer 230, and a transistor gate formed in the logic area over the silicon surface layer 230. An epitaxially grown silicon epitaxial layer 231 is formed on both sides of the transistor gate 240 in the logic area. A conventional sigma shape can be formed on the silicon surface layer 230 via the silicon epitaxial layer 231, to increase the stress and improve the electrical performance of the device.

In the structure shown in FIG. 1, the SONOS structure is a 2T structure, that is, two transistors (a selective transistor and a storage transistor) form a memory cell. A metal salicide is formed in a connection area between the two transistors to reduce the resistance. However, due to the relatively high difficulty in controlling the process, piping may be formed in the connection area between the two transistors of some memory cells. For the SONOS memory cell, voltages of unselected rows accumulate in the connection area during programming, and if there is piping, a very large gate induce drain leakage (GIDL) may occur in the selective transistor, leading to an increase in circuit power consumption and even a programming failure, causing data interference in the storage transistor, and thereby affecting stored data, wherein the impact on mass memories is particularly significant. FIG. 2 illustrates the 2T structure of the storage area of the SONOS memory formed according to the prior art. It can be seen from FIG. 2 that the metal salicide 300 is formed on the upper surface of the connection area between the storage transistor and the selective transistor. Because the metal salicide grows along the crystal lattice, the silicon at the edge reacts faster, thereby forming the piping 301. The edge of the area where the metal salicide is located is a channel of the storage transistor or the selective transistor, that is, the piping 301 is formed in the channel area of the selective transistor or the storage transistor. Therefore, the piping 301 may cause serious damage to the device performance of the SONOS memory.

In view of the above, there is an urgent need for a SONOS memory and a manufacturing method thereof, whereby the problem of piping on the surface of the SONOS memory cell substrate can be solved via simple process steps compatible with the prior art, thereby improving the manufacturing efficiency and product yield of SONOS memories.

### BRIEF SUMMARY

A brief overview of one or more aspects is provided below to provide a basic understanding of these aspects. The overview is not a detailed and comprehensive overview of all the conceived aspects, and is neither intended to identify the key or decisive elements of all the aspects, nor is it attempt to define the scope of any or all of the aspects. The sole purpose is to present some concepts of one or more aspects in a simplified form as a prelude to the more detailed description provided subsequently.

As described above, in order to solve the problem of piping on the surface of a substrate of a SONOS memory cell caused by metal salicide on the surface, one aspect of the present application provides a method for manufacturing a SONOS memory, specifically comprising steps of:

providing a substrate, wherein a selective transistor gate and a storage transistor gate are formed on the substrate of a storage area;

forming a silicon epitaxial layer on the upper surface of the substrate of the storage area on both sides of the selective transistor gate and on both sides of the storage transistor gate, wherein the silicon epitaxial layer is used to separately form a source and a drain of a selective transistor and a storage transistor; and

forming a metal salicide layer on an upper portion of the silicon epitaxial layer.

In an embodiment of the manufacturing method, optionally, the metal salicide layer higher than the upper surface of the substrate is formed on the upper portion of the silicon epitaxial layer.

In an embodiment of the manufacturing method, optionally, the providing a substrate comprises:

providing the substrate comprising a logic area, wherein a gate of a logic device is formed on the substrate of the logic area; and

forming the silicon epitaxial layer comprises:

synchronously forming the silicon epitaxial layer on the upper surface of the substrate of the logic area on both sides of the gate of the logic device.

In an embodiment of the manufacturing method, optionally, an upper portion of the substrate of the logic area further comprises: a bulk silicon layer, a buried oxide layer, and a silicon-on-insulator layer stacked sequentially from bottom to top.

In an embodiment of the manufacturing method, optionally, providing the substrate comprising the logic area and the storage area comprises steps of:

providing an original substrate, wherein the bulk silicon layer, the buried oxide layer, and the silicon-on-insulator layer are stacked sequentially from bottom to top on an upper portion of the original substrate;

forming shallow trench isolation on the upper portion of the original substrate to define the logic area and the storage area;

forming a gate of the logic device over the silicon-on-insulator layer of the logic area; and

removing the buried oxide layer and the silicon-on-insulator layer on the upper portion of the original substrate of the storage area, and forming the selective transistor gate and the storage transistor gate over the bulk silicon layer of the storage area.

In an embodiment of the manufacturing method, optionally, the upper portion of the provided substrate of the storage area further comprises: a storage transistor well and a selective transistor well adjacent to each other, and wherein

the storage transistor gate is formed over the storage transistor well, and the selective transistor gate is formed over the selective transistor well.

In an embodiment of the manufacturing method, optionally, the storage transistor well and the selective transistor well are both formed in a deep well on the upper portion of the substrate of the storage area.

In an embodiment of the manufacturing method, optionally, an ONO storage dielectric layer is provided between the storage transistor gate and the storage transistor well.

In an embodiment of the manufacturing method, optionally, a gate dielectric layer is provided between the selective transistor gate and the selective transistor well.

Another aspect of the present application provides a SONOS memory, wherein the

SONOS memory is formed by any one of the embodiments of the manufacturing method.

According to the method for manufacturing a SONOS memory provided in one aspect of the present application, the negative impact of the piping of the metal salicide on the selective transistor and the storage transistor can be effectively reduced via a process compatible with the existing process, and the yield of the formed SONOS memories is effectively improved, thereby facilitating the improvement of the SONOS memory, in particular the process window and reliability of a memory cell of the mass SONOS memory. In the SONOS memory formed by the manufacturing method provided in another aspect of the present application, since the negative impact of the piping of the metal salicide on the device is reduced, the formed SONOS memory has relatively excellent device performance.

### BRIEF DESCRIPTION OF THE DRAWINGS

By reading the detailed description of the embodiments of the present disclosure with reference to the following drawings, one can better understand the above-mentioned features and advantages of the present application. In the drawings, various components are not necessarily drawn to scale, and components with similar related characteristics or features may have the same or similar reference numerals.

FIG. 1 illustrates a schematic structural diagram of a SONOS memory related to a SOI process in the prior art.

FIG. 2 illustrates a schematic diagram of a structural defect of a memory cell area of the

SONOS memory provided in FIG. 1.

FIG. 3 illustrates a flowchart of a method for manufacturing a SONOS memory provided in one aspect of the present application.

FIGS. 4 and 5 illustrate schematic structural diagrams in a process of forming a SONOS memory according to the method for manufacturing a SONOS memory provided in one aspect of the present application.

### REFERENCE NUMERALS

101 N-type deep well

102 Selective transistor P-type well

103 Storage transistor P-type well

104 Oxide layer

105 Selective transistor gate

106 ONO layer

107 Storage transistor gate

110 First sidewall

120 Second sidewall

210 Logic well

220 Buried oxide layer

230 Silicon surface layer

231 Silicon epitaxial layer

240 Transistor gate

300 Metal salicide

301 Piping

400 Silicon epitaxial layer

500 Metal salicide

501 Piping

### DETAILED DESCRIPTION OF THE DISCLOSURE

The present application is described in detail below with reference to the drawings and specific embodiments. It should be noted that the following aspects described with reference to the drawings and specific embodiments are merely some examples and should not be construed as any limitation on the protection scope of the present application.

The present application relates to semiconductor technology and devices. More specifically, embodiments of the present application provide a method for manufacturing a SONOS memory, wherein by epitaxially growing a silicon epitaxial layer on the upper surface of a substrate in a storage area from which a SOI composite layer is removed and by forming a metal salicide over the silicon epitaxial layer, piping formed during formation of the metal salicide is formed in the silicon epitaxial layer, instead of formed near channels of a storage transistor and a selective transistor in the storage area, and thus imposes no negative impact on the device. The present application also provides other embodiments.

The following description is provided to enable those skilled in the art to implement and use the present application and incorporate it into specific application contexts. Various modifications and various uses in different applications are apparent to those skilled in the art, and the general principles defined herein can be applied to a wide range of embodiments. Therefore, the present application is not limited to the embodiments provided herein, but should be granted the broadest scope consistent with the principles and novel features disclosed herein.

In the following detailed description, many specific details are set forth to provide a more thorough understanding of the present application. However, it is obvious to those skilled in the art that the practice of the present application may not necessarily be limited to these specific details. In other words, the well-known structures and devices are shown in block diagram forms and are not shown in detail, so as to avoid obscuring the present application.

Readers should be noted that all files and documents submitted with this specification and open to the public to consult this specification, and the contents of all of the files and documents are incorporated herein by reference. Unless otherwise stated directly, all the features disclosed in this specification (including any appended claims, abstract, and drawings) can be replaced by alternative features for achieving the same, equivalent, or similar purpose. Therefore, unless otherwise stated expressly, each feature disclosed is only an example of a set of equivalent or similar features.

It should be noted that when used, the left, right, front, rear, top, bottom, head, tail, clockwise, and counterclockwise signs are used for convenience only, and do not imply any specific direction. In fact, they are used to reflect the relative position and/or orientation between various parts of an object.

As used herein, the terms “over”, “under”, “between”, and “on” refer to a relative position of one layer relative to another layer. Likewise, for example, a layer deposited or placed over or under another layer may directly contact the other layer or may be separated from the other layer by one or more intermediate layers. Moreover, a layer deposited or placed between layers may directly contact the layers or may be separated from the layers by one or more intermediate layers. In contrast, a first layer “on” a second layer is in contact with the second layer. In addition, a relative position of one layer relative to the other layers is provided (assuming that deposition, modification, and film removal operations are performed relative to a base substrate, regardless of the absolute orientation of the substrate).

The manufacturing method provided by the present application is described below in detail with reference to the drawings. The drawings are provided as examples only and should not unduly limit the scope of the claims. Those skilled in the art would conceive of many variations, alternatives, and modifications. Depending on the implementation, one or more steps may be added, removed, repeated, rearranged, modified, replaced, and/or overlapped, without affecting the protection scope of the claims.

As described above, in order to solve the problem of piping formed during formation of a metal salicide between a storage transistor and a selective transistor that causes negative impact on the performance of the storage transistor and the selective transistor in the prior art, the present application provides a SONOS memory and a manufacturing method thereof. First, reference is made to FIG. 3, which illustrates a flowchart of a method for manufacturing a SONOS memory provided in one aspect of the present application. Referring to FIG. 3, the method for manufacturing a SONOS memory provided in one aspect of the present application specifically includes: step S110: a substrate is provided, wherein a selective transistor gate and a storage transistor gate are formed on the substrate of a storage area; step S120: a silicon epitaxial layer is formed on the upper surface of the substrate of the storage area on both sides of the selective transistor gate and on both sides of the storage transistor gate, to separately form a source and a drain; and step S130: a metal salicide layer is formed on an upper portion of the silicon epitaxial layer.

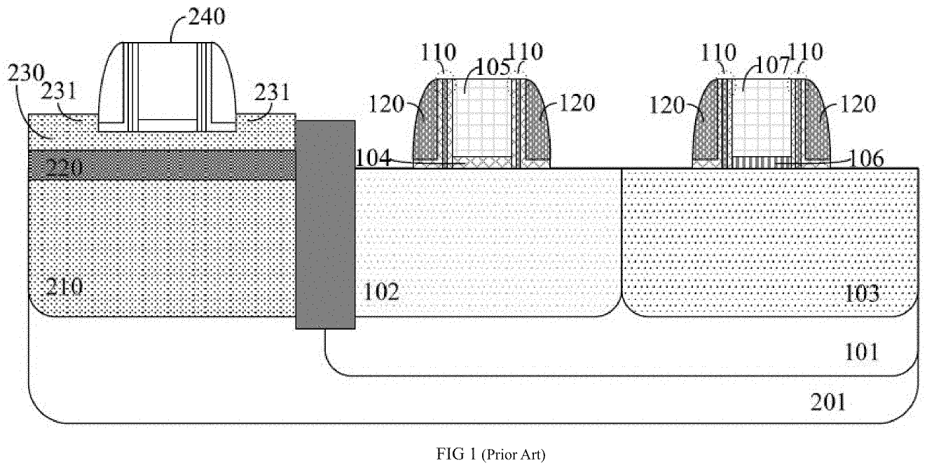

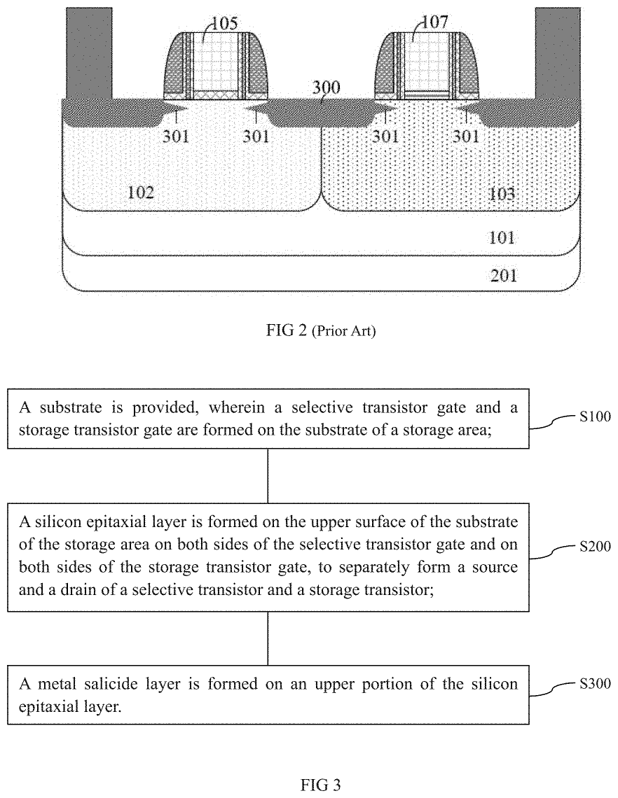

Reference is made to FIG. 1 to understand the substrate and the selective transistor gate and the storage transistor gate formed on the substrate of the storage area provided in the above step S110. Similar to the prior art, the method for manufacturing a SONOS memory provided by the present application is constructed under FDSOI, wherein a SOI layer on an upper portion of the substrate of the storage area needs to be etched and removed, that is, a storage device in the storage area is formed in the conventional bulk silicon substrate, so that a high-voltage operation of the SONOS memory device is not affected by the SOI layer.

It can be seen from FIG. 1 that, the substrate 201 of the storage area provided in one aspect of the present application is provided with: an N-type deep well 101; a selective transistor P-type well 102 and a storage transistor P-type well 103 adjacent to each other; a selective transistor gate 105 isolated from the selective transistor well 102 via an oxide layer 104; and a storage transistor gate 107 isolated from the storage transistor well 103 via an ONO layer 106. The outer sides of the selective transistor gate 105 and the storage transistor gate 107 are each provide with a first sidewall 110 and a second sidewall 120.

More specifically, the first sidewall includes an ONO structure. Generally, the thickness of the first sidewall 110 determines the distance from the ion implantation position in a source-drain extension region to the gate, and the thickness of the second sidewall 120 defines the distance from the gate to the source and drain.

The oxide layer 104 serves as a gate dielectric layer between the selective transistor gate and the substrate. In other embodiments, the gate dielectric layer may be formed of other existing or future gate dielectric materials, which are not limited to the oxide.

The ONO layer 106 serves not only as a gate dielectric layer between the storage transistor gate and the substrate, but also as a storage dielectric layer of the storage transistor. In other embodiments, those skilled in the art could select a functional layer between the storage transistor gate and the substrate by using an existing or future technology, which is not limited to the ONO layer.

Those skilled in the art should understand that the substrate 201 may also be P-type doped, the N-type deep well 101 is N-type doped, and the selective transistor P-type well 102 and the storage transistor P-type well 103 are P-type doped, wherein the adjustment is performed specifically according to the actual required device type. The formation of a well may include three to five steps, including but not limited to steps of epitaxial growth, original oxidation growth, ion implantation using a mask, secondary high-energy ion implantation, and annealing.

Regarding the logic area, since the SOI structure is not removed in advance from the substrate thereof, the substrate of the logic area further includes a bulk silicon layer 210, a buried oxide layer 220, and a silicon-on-insulator layer 230 stacked sequentially from bottom to top. The gate of the logic device is formed over the silicon-on-insulator layer 230, and the silicon epitaxial layer 231 formed on the substrate of the logic area is formed on the upper surface of the silicon-on-insulator layer 230.

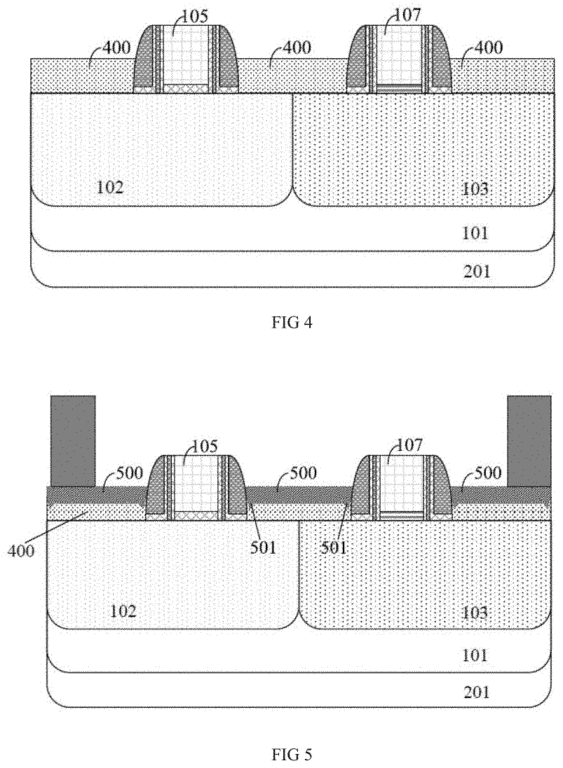

As described above, in order to reduce the resistance, a metal salicide can be formed in a connection area between the selective transistor and the storage transistor of the 2T SONOS memory. Reference is made to FIG. 4 to understand step S120 of the manufacturing method provided in one aspect of the present application, in the manufacturing method provided by the present application, in order to avoid the negative impact of the formation of the metal salicide on the device performance of the SONOS memory, the silicon epitaxial layer 400 is formed on the upper surface of the substrate of the storage area on both sides of the selective transistor gate and on both sides of the storage transistor gate, to form the source and the drain separately.

In the above embodiment, those skilled in the art could form the silicon epitaxial layer 400 according to an existing or future method, and a specific implementation method of the silicon epitaxial layer 400 should not unduly limit the protection scope of the present application.

It can be understood that, in an example embodiment, step 120 of forming the silicon epitaxial layer 400 in the storage area can be completed synchronously with the formation of a silicon epitaxial layer 231 on the upper surface of the silicon-on-insulator layer 230 in the logic area on both sides of the gate of the logic device, thereby saving technological process steps.

Subsequently, step S130 is performed: the metal salicide layer 500 is formed on the upper portion of the silicon epitaxial layer 400. Reference is made to FIG. 5, which illustrates a schematic structural diagram obtained after the metal salicide layer 500 is formed on the upper portion of the silicon epitaxial layer 400. It can be seen from FIG. 5 that the formed metal sslicide layer 500 is still higher than the upper surface of the substrate, i.e., higher than the upper surfaces of the selective transistor P-type well 102 and the storage transistor P-type well 103.

Since the metal salicide layer 500 grows along the crystal lattice, the metal salicide layer reacts with the silicon in the silicon epitaxial layer 400. The silicon at the corner reacts faster, and therefore, the piping 501 is easy to be formed. However, in the method for manufacturing a SONOS memory provided in one aspect of the present application, since the silicon epitaxial layer 400 is formed in advance and the metal salicide layer 500 is formed on the upper portion of the silicon epitaxial layer 400, although the piping 501 is formed, the piping 501 is formed in the silicon epitaxial layer 400. The piping 501 formed in the silicon epitaxial layer 400 is away from the selective transistor well 102 and the storage transistor well 103, i.e., away from channel regions under the selective transistor gate 105 and the storage transistor gate 107, and therefore, the piping 501 imposes no negative impact on the SONOS memory.

In addition, both sides of the silicon epitaxial layer 400 are respectively provided with the sidewalls on both sides of the selective transistor gate 105 and the storage transistor gate 107. Due to the existence of the sidewalls, the lateral growth of the piping 501 is prevented, thereby eliminating the impact on the performance of the selective transistor gate 105 and the storage transistor gate 107.

It can be understood that the formation of the metal salicide can be implemented according to an existing or future process. Even if the process of forming the metal saicide may be improved in the future to solve the problem of the piping formed during the formation of the metal saicide, the method for manufacturing a SONOS memory provided by one aspect of the present application still adopts the mode in which the formation of the metal saicide is away from the channel, to reduce the negative impact of the formation of the metal salicide on the SONOS memory as much as possible.

So far, the method for manufacturing a SONOS memory provided in one aspect of the present application is described above. According to the method for manufacturing a SONOS memory provided in one aspect of the present application, the negative impact of the piping of the metal salicide on the selective transistor and the storage transistor can be effectively reduced via a process compatible with the existing process, and the yield of the formed SONOS memories is effectively improved, thereby facilitating the improvement of the SONOS memory, in particular the process window and reliability of a memory cell of the mass SONOS memory.

Another aspect of the present application provides the SONOS memory formed according to the above manufacturing method. The structure of the storage area is shown in FIG. 5, and for the structure of the logic area, reference is made to the existing structure shown in FIG. 1. In the SONOS memory formed by the manufacturing method provided in another aspect of the present application, since the negative impact of the piping of the metal salicide on the device is reduced, the formed SONOS memory has relatively excellent device performance.

Therefore, the embodiments of the SONOS memory and the manufacturing method thereof are described above. Although the present disclosure is described with respect to specific exemplary embodiments, it is obvious that various modifications and changes can be made to these embodiments without departing from the broader spirit and scope of the present disclosure. Therefore, the specification and drawings should be construed as being illustrative rather than restrictive.

It should be understood that this specification will not be used to interpret or limit the scope or meaning of the claims. In addition, in the foregoing detailed description, it can be seen that various features are combined together in a single embodiment for the purpose of simplifying the present disclosure. The method of the present disclosure should not be construed as reflecting that the claimed embodiments require more features than those explicitly listed in each claim. On the contrary, as reflected in the appended claims, the inventive subject matter includes features less than all the features of a single disclosed embodiment. Therefore, the appended claims are hereby incorporated into the detailed description, with each claim independently used as an independent embodiment.

An embodiment or embodiments mentioned in the description are intended to be included in at least one embodiment of a circuit or method in combination with the specific features, structures, or characteristics described in the embodiment. The phrase “an embodiment” in various portions of the specification does not necessarily refer to the same embodiment.

What is claimed is:

1. A method for manufacturing a SONOS memory, comprising steps of:
providing a substrate, wherein a selective transistor gate and a storage transistor gate are formed on the substrate of a storage area;
forming a silicon epitaxial layer on the upper surface of the substrate of the storage area on both sides of the selective transistor gate and on both sides of the storage transistor gate, wherein the silicon epitaxial layer is used to separately form a source and a drain of a selective transistor and a storage transistor; and
forming a metal salicide layer on an upper portion of the silicon epitaxial layer.

2. The manufacturing method according to claim 1, wherein the metal salicide layer higher than the upper surface of the substrate is formed on the upper portion of the silicon epitaxial layer.

3. The manufacturing method according to claim 1, wherein the providing the substrate comprises:
providing the substrate comprising a logic area, wherein a gate of a logic device is formed on the substrate of the logic area; and
forming the silicon epitaxial layer comprises:
synchronously forming the silicon epitaxial layer on the upper surface of the substrate of the logic area on both sides of the gate of the logic device.

4. The manufacturing method according to claim 3, wherein an upper portion of the substrate of the logic area further comprises: a bulk silicon layer, a buried oxide layer, and a silicon-on-insulator layer stacked sequentially from bottom to top.

5. The manufacturing method according to claim 4, wherein providing the substrate comprising the logic area and the storage area comprises steps of:
providing an original substrate, wherein the bulk silicon layer, the buried oxide layer, and the silicon-on-insulator layer are stacked sequentially from bottom to top on an upper portion of the original substrate;
forming shallow trench isolation on the upper portion of the original substrate to define the logic area and the storage area;
forming a gate of the logic device over the silicon-on-insulator layer of the logic area; and
removing the buried oxide layer and the silicon-on-insulator layer on the upper portion of the original substrate of the storage area, and forming the selective transistor gate and the storage transistor gate over the bulk silicon layer of the storage area.

6. The manufacturing method according to claim 1, wherein the upper portion of the provided substrate of the storage area further comprises: a storage transistor well and a selective transistor well adjacent to each other, and wherein
the storage transistor gate is formed over the storage transistor well, and the selective transistor gate is formed over the selective transistor well.

7. The manufacturing method according to claim 6, wherein the storage transistor well and the selective transistor well are both formed in a deep well on the upper portion of the substrate of the storage area.

8. The manufacturing method according to claim 6, wherein an ONO storage dielectric layer is provided between the storage transistor gate and the storage transistor well.

9. The manufacturing method according to claim 6, wherein a gate dielectric layer is provided between the selective transistor gate and the selective transistor well.

10. A SONOS memory, wherein the SONOS memory is formed by the manufacturing method according to claim 1.
